(19) United States
(12) Patent Application Publication
(10) Pub. No.: US 2024/0408649 A1
(43) Pub. Date: Dec. 12, 2024

(54) SUBSTRATE CLEANING DEVICE AND SUBSTRATE POLISHING DEVICE

(71) Applicant: EBARA CORPORATION, Tokyo (JP)

(72) Inventor: Erina BABA, Tokyo (JP)

(21) Appl. No.: 18/733,438

(22) Filed: Jun. 4, 2024

(30) Foreign Application Priority Data
Jun. 6, 2023 (JP) 2023-093012

(51) Int. Cl. B08B 3/02; B08B 15/00

(52) U.S. Cl. CPC B08B 3/02; B08B 15/00

(57) ABSTRACT

A substrate cleaning device for cleaning a surface of a substrate having been polished is provided in correspondence with a cleaning position of the top ring. The substrate cleaning device includes: a first spray unit that sprays cleaning liquid toward the substrate present in the cleaning position; and a second spray unit that sprays cleaning liquid toward the substrate present in the cleaning position. The second spray unit is provided on either a downstream side or an upstream side of the first spray unit, with respect to a rotation direction of the top ring present in the cleaning position. A spray nozzle structuring the second spray unit is tilted toward the first spray unit. The second spray unit urges the cleaning liquid sprayed from the first spray unit toward the outer circumferential part of the substrate.

### CROSS REFERENCE TO RELATED APPLICATION

This application claims priority to Japanese Patent Application No. 2023-093012 filed Jun. 6, 2023, the entire contents of which are hereby incorporated by reference.

### BACKGROUND OF THE INVENTION

### Field of the Invention

The present invention is related to a device for cleaning a substrate such as a semiconductor wafer and a substrate polishing device including such a cleaning device.

### Description of the Related Art

A polishing device for polishing a surface of a substrate such as a semiconductor wafer includes a polishing module, a cleaning module, and a substrate transporting mechanism. The polishing module includes a polishing table having a polishing pad and a polishing head (a top ring) for holding a substrate. The polishing head transports the substrate between a handover position in which the substrate is handed over and a polishing position in which the substrate overlaps with the polishing pad. In the polishing position, a substrate surface is pressed against the polishing pad with prescribed pressure, and the polishing pad and the substrate are caused to have relative movement while polishing liquid (a slurry) is supplied, so that the substrate is brought into sliding contact with the polishing pad, and the substrate surface is polished to achieve a prescribed coating thickness.

The cleaning module includes a plurality of cleaning modules that perform a rough cleaning process (primary cleaning) and a finishing cleaning process (secondary cleaning) on the substrate surface and eliminates polishing residues (particles) such as the polishing liquid and polishing shavings remaining on the substrate after the polishing process. The cleaning module is provided with a plurality of cleaning lines for cleaning a plurality of substrate (Japanese Patent Laid-Open No. 2010-50436).

Particles remaining on surfaces of substrate after the polishing process affect yield of semiconductor devices. Thus, it is desirable to eliminate such particles before the substrate are handed over to the cleaning module. To cope with this problem, hitherto disclosed (Japanese U.S. Pat. No. 6,055,648) is a polishing device configured to perform a cleaning process on a substrate having been polished, by spraying cleaning liquid from a cleaning nozzle provided underneath the substrate while rotating the substrate held by a top ring, in a cleaning position being a lateral position, relative to a polishing table in a polishing module.

### SUMMARY OF THE INVENTION

When the cleaning process is performed by spraying the cleaning liquid from the cleaning nozzle provided underneath the substrate, while the substrate is rotated, although the cleaning liquid containing the particles is discharged to the outside from the outer circumference of the substrate by centrifugal force associated with the substrate rotation, the cleaning liquid sprayed onto the vicinity of the center of the substrate does not get easily discharged to the outside of the substrate, because centrifugal force acting thereon is relatively small. Further, a part of the cleaning liquid stays in the vicinity of the center of a substrate W, and as a result, particles may re-adhere to the substrate. For this reason, a need has arisen to efficiently discharge the cleaning liquid containing the particles, to the outside.

One aspect of the present invention provides a substrate cleaning device that cleans a surface of a substrate having been polished and is provided for a polishing device including a polishing table having a polishing surface for performing substrate polishing and a top ring for holding and pressing the substrate against the polishing surface by using a membrane while causing a retainer ring to surround an outer circumferential part of the substrate. The top ring is movable between a polishing position where the substrate polishing is performed above the polishing table and a handover position where the substrate is handed over in a lateral position relative to the polishing table. The substrate cleaning device is provided in correspondence with a cleaning position between the polishing position and the handover position. The substrate cleaning device comprises: a first spray unit that sprays cleaning liquid toward the substrate present in the cleaning position; and a second spray unit that sprays cleaning liquid toward the substrate present in the cleaning position. The second spray unit is provided on either a downstream side or an upstream side of the first spray unit, with respect to a rotation direction of the top ring present in the cleaning position. The cleaning liquid from the second spray unit urges the cleaning liquid sprayed from the first spray unit toward the outer circumferential part of the substrate. A spray nozzle structuring the second spray unit is tilted toward the first spray unit.

### BRIEF DESCRIPTION OF THE DRAWINGS

FIG. 1 is a plan view showing a schematic configuration of a substrate polishing device including a substrate cleaning device according to an embodiment of the present invention;

FIG. 2 is a plan view showing a configuration of a polishing unit;

FIG. 3 is a perspective view of the polishing unit in FIG. 2;

FIG. 4 is a schematic cross-sectional view showing an internal configuration of a top ring in the polishing unit in FIG. 2;

FIG. 5 is a plan view for explaining a manner in which a substrate moves between a handover position, a cleaning position, and a polishing position;

FIG. 6 is a plan view showing a configuration of an auxiliary cleaning unit;

FIG. 7 is another plan view showing the configuration of the auxiliary cleaning unit and depicts a manner in which cleaning liquid is sprayed from substrate cleaning nozzles and assisting nozzles;

FIG. 8 is an explanatory drawing showing an example of cleaning liquid spray positions from the substrate cleaning nozzles and the assisting nozzles;

FIG. 9 is an explanatory drawing for showing a positional relationship between the substrate cleaning nozzles and the assisting nozzles;

FIG. 10A to 10D are explanatory drawings showing an example of liquid squirt positions from the substrate cleaning nozzles;

FIG. 11 is a side view of the auxiliary cleaning unit;

FIG. 12 is an explanatory drawing showing a desirable range for placing the assisting nozzles;

FIG. 13 is a functional block diagram showing a configuration of a substrate polishing device;

FIG. 14 is a flowchart of substrate polishing and cleaning processes;

FIG. 15 is a plan view showing a configuration of another example of the auxiliary cleaning unit;

FIG. 16 is an explanatory drawing showing an example of cleaning liquid spray positions from substrate cleaning nozzles and assisting nozzles, regarding the auxiliary cleaning unit in FIG. 15;

FIG. 17 is an explanatory drawing showing a positional relationship between the substrate cleaning nozzles and the assisting nozzles, regarding the auxiliary cleaning unit in FIG. 15;

FIG. 18 is an explanatory drawing showing a desirable range for placing the assisting nozzles, regarding the auxiliary cleaning unit in FIG. 16;

FIG. 19 is an explanatory drawing showing an example of cleaning liquid spray positions from substrate cleaning nozzles and assisting nozzles, regarding a yet another example of the auxiliary cleaning unit;

FIG. 20 is an explanatory drawing showing a positional relationship between the substrate cleaning nozzles and the assisting nozzles, regarding the auxiliary cleaning unit in FIG. 19; and

FIG. 21 is a flowchart showing examples of operations of the substrate cleaning nozzles and the assisting nozzles.

### DETAILED DESCRIPTION OF THE PREFERRED EMBODIMENTS

### First Embodiment

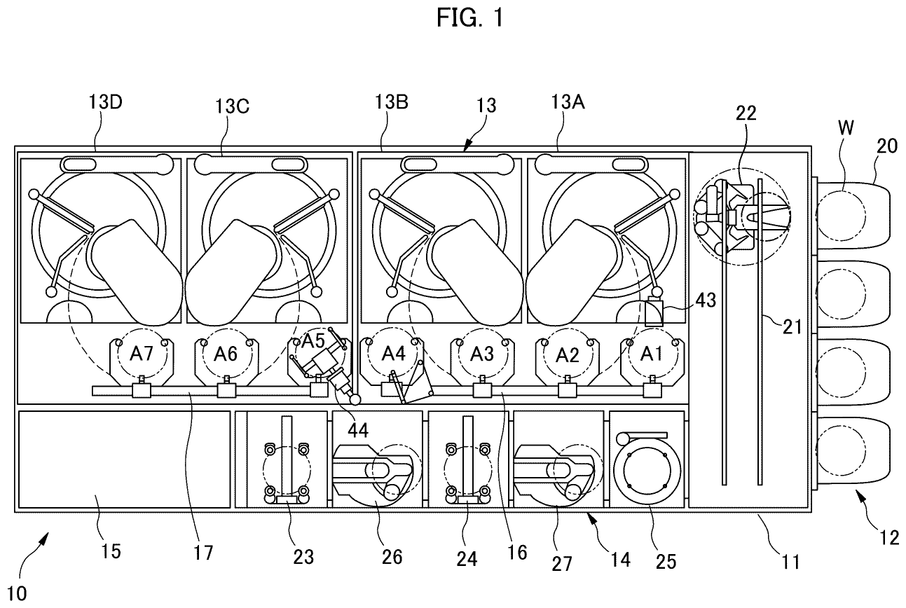

A first embodiment of the present invention will be described below, with reference to the drawings. FIG. 1 schematically shows a configuration of a substrate polishing device including a substrate cleaning device according to the present embodiment. A substrate polishing device 10 includes a rectangular housing 11 and is divided by partition walls into a loading/unloading section 12, a polishing section 13, and a cleaning section 14. Further, the substrate polishing device 10 includes a controlling unit 15 that controls operations of functional units thereof.

The loading/unloading section 12 includes a plurality of front loading units to be set with substrate cassettes 20 for storing therein a large number of substrate W such as semiconductor wafers. In the loading/unloading section 12, a travel mechanism 21 is placed along an array of the substrate cassettes 20. Installed on the travel mechanism 21 is a transporting robot 22 capable of moving along the direction in which the substrate cassettes 20 are arranged. The transporting robot 22 transports pre-polishing substrate W received from the substrate cassettes 20 toward the polishing section 13 and receives post-polishing/cleaning substrate W from the cleaning section 14.

The polishing section 13 includes a plurality of polishing units 13A to 13D for polishing (planarizing) the substrate W. The first to the fourth polishing units 13A to 13D are arranged along the longitudinal direction of the substrate polishing device 10. Details of configurations of the polishing unit will be described later.

A first linear transporter 16 is provided so as to be adjacent to the first polishing unit 13A and the second polishing unit 13B. The first linear transporter 16 transports the substrate W between four transport positions (namely, first to fourth transport positions A1 to A4 serially numbered from the side closer to the loading/unloading section 12) provided along the direction in which the polishing units 13A and 13B are arranged.

A second linear transporter 17 is provided so as to be adjacent to the third polishing unit 13C and the fourth polishing unit 13D. The second linear transporter 17 transports the substrate W between three transport positions (namely, fifth to seventh transport positions A5 to A7 serially numbered from the side closer to the loading/unloading section 12) provided along the direction in which the polishing units 13C and 13D are arranged.

The cleaning section 14 has stored therein a first cleaning unit 23 and a second cleaning unit 24 that clean post-polishing substrate W and a drying unit 25 that dries post-cleaning substrate W. Provided between the first cleaning unit 23 and the second cleaning unit 24 is a first transporting unit 26 that hands over the substrate W between these two cleaning units. In addition, provided between the second cleaning unit 24 and the drying unit 25 is a second transporting unit 27 that hands over the substrate W between these two units.

Within the first cleaning unit 23, a plurality of (e.g., two) primary cleaning modules are provided in top and bottom positions. Similarly, within the second cleaning unit 24, a plurality of (e.g., two) secondary cleaning modules are provided in top and bottom positions. The primary cleaning modules and the secondary cleaning modules are cleaning machines that clean the substrate by using cleaning liquid. By arranging the cleaning modules in the top and bottom positions, it is possible to keep footprints thereof small.

As the primary cleaning modules and the secondary cleaning modules, it is possible to use cleaning machines of a roll sponge type. The primary cleaning modules and the secondary cleaning modules may be cleaning modules of mutually the same type or may be cleaning modules of mutually-different types. For example, it is acceptable to configure the primary cleaning modules with cleaning machines of a type in which a pair of roll sponges scrub and clean the top and the bottom surfaces of the substrate and to configure the secondary cleaning modules with cleaning machines of a pencil sponge type or cleaning machines of a two-fluid jet type.

Within the drying unit 25, a plurality of (e.g., two) drying modules are provided in top and bottom positions. Each of the substrate W is dried by blowing gas from a nozzle (not shown) toward the substrate W that is rotating. Alternatively, each of the substrate W may be rotated at a high speed so that the substrate W is dried with centrifugal force. The transporting robot 22 takes out, from the drying unit 25, the substrate W having been cleaned and dried and returns the substrate W to the substrate cassettes 20.

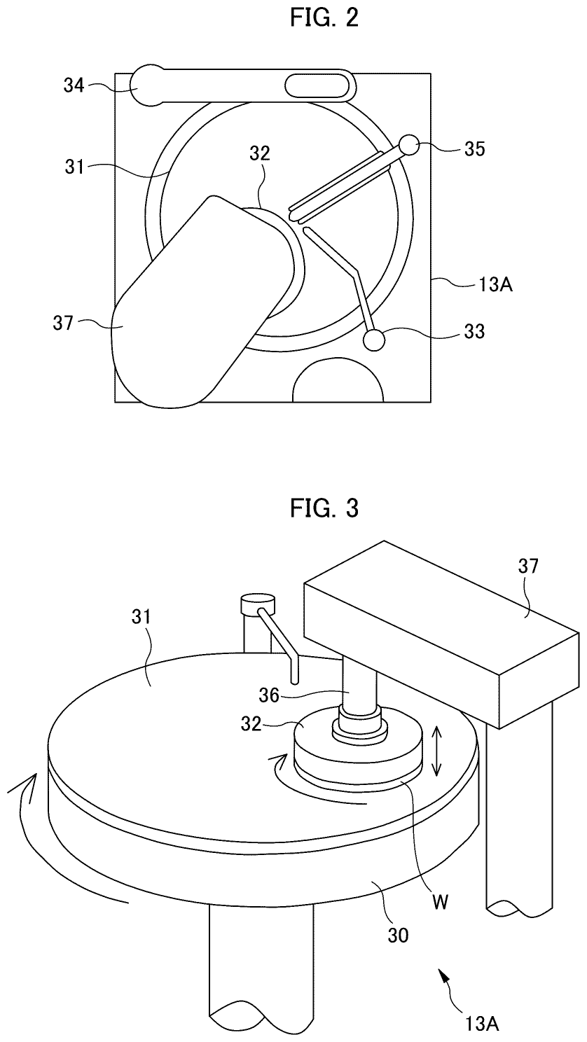

FIGS. 2 and 3 each show a schematic configuration of the first polishing unit 13A according to the present embodiment. Because the second to the fourth polishing units 13B to 13D each have the same configuration as the first polishing unit 13A, the following will describe the first polishing unit 13A.

The first polishing unit 13A includes: a polishing table 30 to which a polishing pad 31 having a polishing surface is attached; a top ring 32 used for polishing any one of the substrate W while holding and pressing the substrate W against the polishing pad 31 on the polishing table 30 with prescribed pressure; a polishing liquid supply nozzle 33 for supplying the polishing liquid or dressing liquid (e.g., pure water) to the polishing pad 31; a dresser 34 for dressing the polishing surface of the polishing pad 31; and an atomizer 35 that atomizes a fluid mixture of liquid (e.g., pure water) and gas (e.g., nitrogen gas) or liquid (e.g., pure water) and sprays the polishing surface therewith. The top ring 32 is configured to be able to revolve by a swing arm 37 connected thereto via a top ring shaft 36.

The polishing pad 31 pasted on the polishing table 30 constitutes the polishing surface for polishing the substrate W. It is also acceptable to use fixed abrasive grains, in place of the polishing pad 31. The top ring 32 and the polishing table 30 are each configured to rotate on an axial center thereof (see the arrows in FIG. 3). The substrate W is held on the bottom face of the top ring 32 by vacuum adsorption. The polishing liquid is supplied from the polishing liquid supply nozzle 33 to the top face (the polishing surface) of the polishing pad 31, so that the substrate W is polished while being pressed against the polishing pad 31 by the top ring 32.

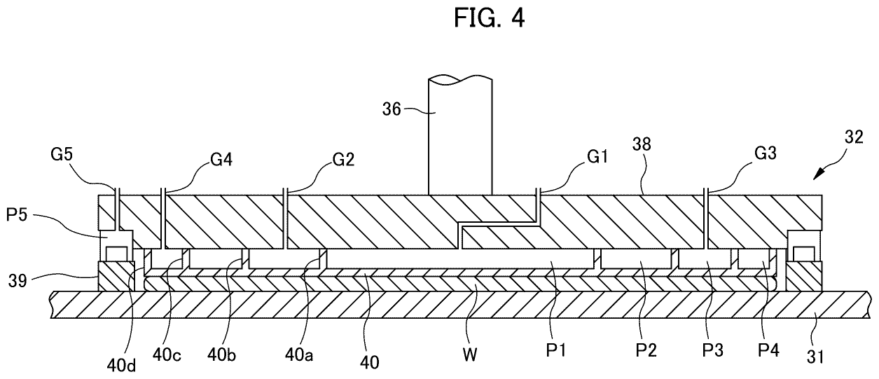

In FIG. 4, the top ring 32 is coupled to the lower end of the top ring shaft 36 via a universal joint (not shown) being a ball joint. The top ring 32 includes: a top ring main body 38 having a substantially disc-like shape; a retainer ring 39 provided in a lower part of the top ring main body 38; and a circular membrane (a flexible pad) 40 to abut against the substrate W. The top ring main body 38 is formed by using a material having high strength and rigidity such as metal or ceramics. Further, the retainer ring 39 is formed by using a resin material or ceramics having high rigidity.

The membrane 40 is attached to the bottom face of the top ring main body 38. Between the membrane 40 and the top ring main body 38, a plurality of pressure chambers (air bags) P1, P2, P3, and P4 are formed by a plurality of partition walls 40a to 40d provided on the membrane 40. The pressure chambers P1, P2, P3, and P4 have pressured fluid such as pressured air supplied thereto and are also vacuumized, via fluid paths G1, G2, G3, and G4, respectively. The pressure chamber P1 at the center is circular, whereas the other pressure chambers P2, P3, and P4 each have an annular shape. The pressure chambers P1, P2, P3, and P4 are arranged concentrically.

It is possible to change the inside pressure of the pressure chambers P1, P2, P3, and P4 independently of one another, by using a pressure adjusting unit (not shown). Thus, it is possible to independently adjust pressing force onto four regions of the substrate W, namely, a central part, an inner intermediate part, an outer intermediate part, and a peripheral part.

In order to prevent the substrate W during a polishing process from jumping out of the top ring 32, the retainer ring 39 provided on the bottom face of the top ring 32 holds the substrate W while surrounding an outer circumferential part thereof. An opening is formed in a part of the membrane 40 structuring the pressure chamber P3 so that, by creating a vacuum in the pressure chamber P3, the substrate W is adsorbed and held by the top ring 32. Further, by supplying nitrogen gas, dry air, compressed air, or the like to the pressure chamber P3, the substrate W is released from the top ring 32.

Between the retainer ring 39 and the top ring main body 38, a flexible bag forming the pressure chamber P5 is provided. The retainer ring 39 is able to move up and down, relative to the top ring main body 38. A fluid path G5 is allowed to communicate with the pressure chamber P5, so that the pressured fluid such as pressured air is supplied to the pressure chamber P5 through the fluid path G5. It is possible to adjust the inside pressure of the pressure chamber P5 by using the pressure adjusting unit. Independently of the pressing force on the substrate W, it is possible to adjust pressing force on the polishing pad 31 on the retainer ring 39.

Each substrate may be polished by any one of the first polishing unit 13A, the second polishing unit 13B, the third polishing unit 13C, and the fourth polishing unit 13D. Alternatively, each substrate may sequentially be polished by two or more polishing units selected in advance from among the polishing units 13A to 13D. It is possible to enhance throughputs, by equalizing polishing periods among all the polishing units 13A to 13D.

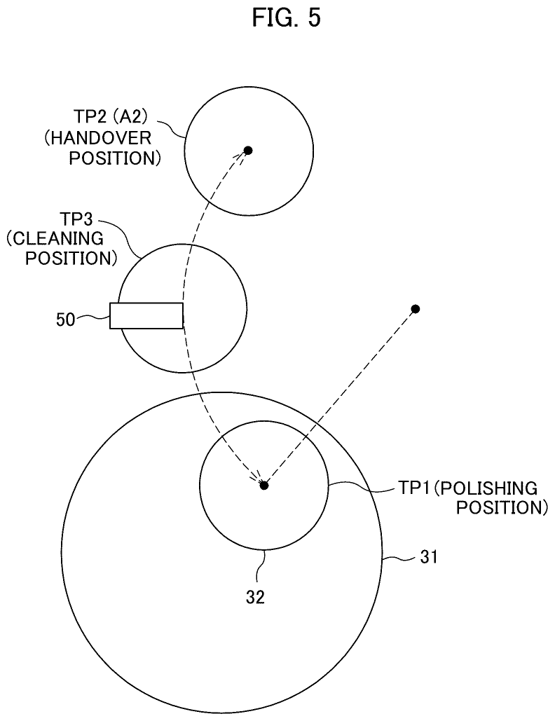

In FIG. 1, the substrate W is transported to the polishing units 13A, 13B by the first linear transporter 16. The top ring 32 of the first polishing unit 13A moves between a polishing position above the polishing table 30 (the reference character is omitted from FIG. 5; the polishing pad 31) and a second transport position A2 being a lateral position relative to the polishing table 30. The handover of the substrate to the top ring 32 is performed in the second transport position A2, so that the second transport position A2 serves as a handover position TP2 (see FIG. 5).

Similarly, the top ring of the second polishing unit 13B (or the third polishing unit 13C, the fourth polishing unit 13D) moves between a polishing position above the polishing table (the polishing pad) and a third transport position A3 (a sixth transport position A6 for the third polishing unit 13C; and a seventh transport position A7 for the fourth polishing unit 13D) being a lateral position relative to the polishing table. The handover of the substrate to the top ring is performed in the third transport position A3 (or the sixth transport position A6, the seventh transport position A7) which serves as a substrate handover position.

In the first transport position A1, a lifter 43 used for receiving a substrate from the transporting robot 22 is provided. The substrate is handed over from the transporting robot 22 to the first linear transporter 16 via the lifter 43. Further, provided between the first linear transporter 16, the second linear transporter 17, and the cleaning section 14 are swing transporters 44 that have a reversing function and hand over a substrate from the first linear transporter 16 to the second linear transporter 17 and transport a substrate from the polishing section 13 to the cleaning section 14.

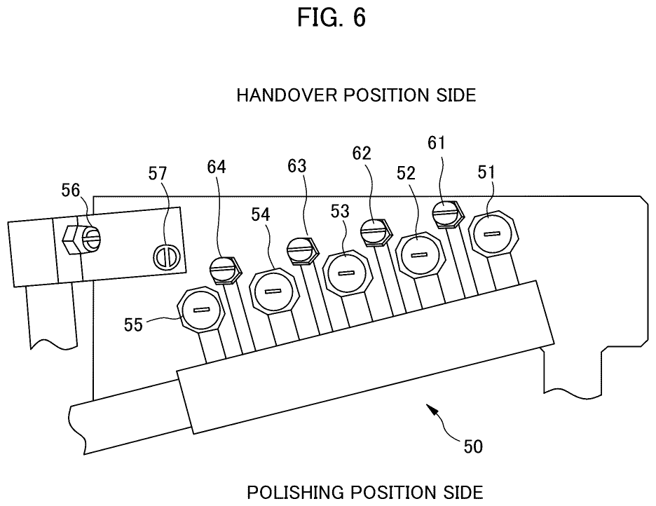

The top ring 32 of the first polishing unit 13A is configured to move between a polishing position TP1 above the polishing table 30 (the reference character is omitted from FIG. 5; the polishing pad 31) and the substrate handover position TP2 (A2 in FIG. 1) being the lateral position relative to the polishing table 30. The top ring 32 of the first polishing unit 13A is further configured to stop at a cleaning position TP3 between the polishing position TP1 and the substrate handover position TP2 (the second transport position A2). An auxiliary cleaning unit 50 (see FIG. 6) is provided in a position corresponding to the cleaning position TP3 of the top ring 32.

FIG. 5 schematically shows a positional relationship among the polishing table 30 (the reference character is omitted from FIG. 5; the polishing pad 31), the top ring 32, and the auxiliary cleaning unit 50 of the first polishing unit 13A. The top ring 32 is configured to be able to revolve by the swing arm 37 connected thereto via the top ring shaft 36 and is configured so as to move between the polishing position TP1 above the polishing table 30, the handover position TP2 (the second transport position A2) being the lateral position relative to the polishing table 30, and the cleaning position TP3 between the polishing position TP1 and the handover position TP2. The auxiliary cleaning unit 50 is provided in the position corresponding to the cleaning position TP3 of the top ring 32.

Because the configurations of the top ring 32 and the auxiliary cleaning unit 50 described above are the same for the second to the fourth polishing units 13B to 13D, detailed descriptions thereof will be omitted. The auxiliary cleaning unit 50 may be provided for each of all the first to the fourth polishing units 13A to 13D. Alternatively, the auxiliary cleaning unit 50 may be omitted from a part of the polishing units.

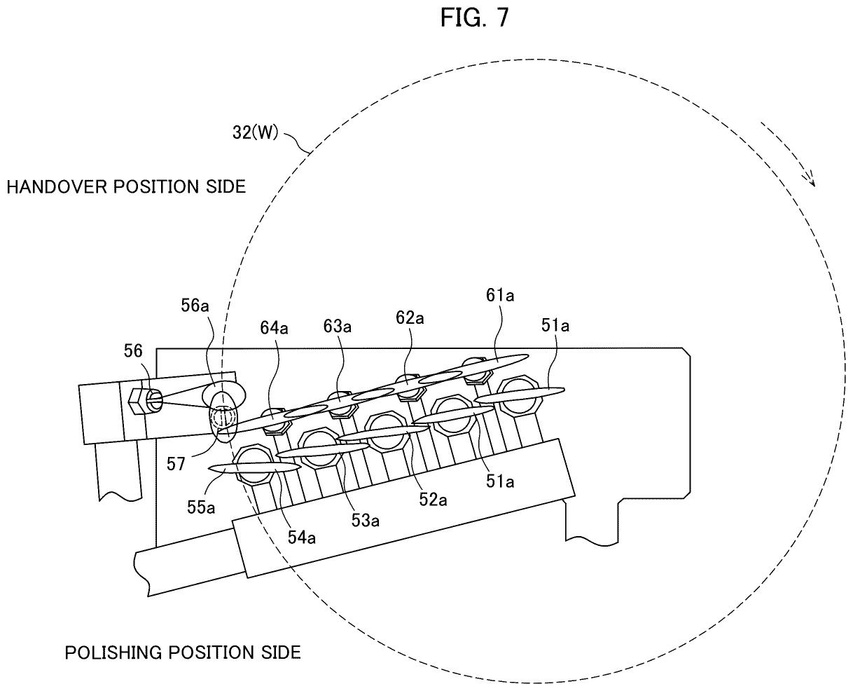

FIGS. 6 and 7 are plan views showing a configuration of the auxiliary cleaning unit 50. The auxiliary cleaning unit 50 includes a plurality of (five in the present embodiment) substrate cleaning nozzles 51 to 55, a retainer ring (RR) lateral face cleaning nozzle 56, a RR-membrane gap cleaning nozzle 57, and a plurality of (four in the present embodiment) assisting nozzles 61 to 64. The auxiliary cleaning unit 50 performs a cleaning process on a post-polishing substrate W present in the cleaning position TP3 and the top ring 32 holding the substrate. With this configuration, it is possible to perform the cleaning process before the post-polishing substrate W is transported to the cleaning section 14, and it is therefore possible to effectively eliminate particles remaining on the surfaces of the substrate.

The substrate cleaning nozzles 51 to 55 structure a spray unit for cleaning the substrate and are two-fluid nozzles for example. The substrate cleaning nozzles 51 to 55 serve as cleaning machines that mix liquid with gas and blow the fluid mixture (the cleaning liquid) onto the surfaces of the substrate, while being capable of eliminating small particles on the substrate with small droplets and impact energy. When the top ring 32 is in the cleaning position TP3, the substrate cleaning nozzles 51 to 55 are linearly arranged along the radial direction while being positioned underneath the top ring 32. The substrate cleaning nozzles 51 to 55 spray the cleaning liquid upward from the bottom side of the substrate W onto the surface of the substrate W that is rotating in the cleaning position TP3 together with the top ring 32, in the direction of the arrow shown in FIG. 7.

The substrate cleaning nozzles 51 to 55 may be selected from among: nozzles that pressure and spray a fluid mixture (two fluids) of liquid (e.g., pure water) and gas; nozzles that generate a high-speed jet spray; and nozzles that apply ultrasound waves. As for the type of the liquid to be supplied to the substrate cleaning nozzles 51 to 55, it is possible to use, for example, pure water, an acidic or alkaline chemical solution or surfactant, liquid containing a small amount of carbon dioxide for inhibiting static electricity, water saturated with N₂ gas, or water containing fine bubbles.

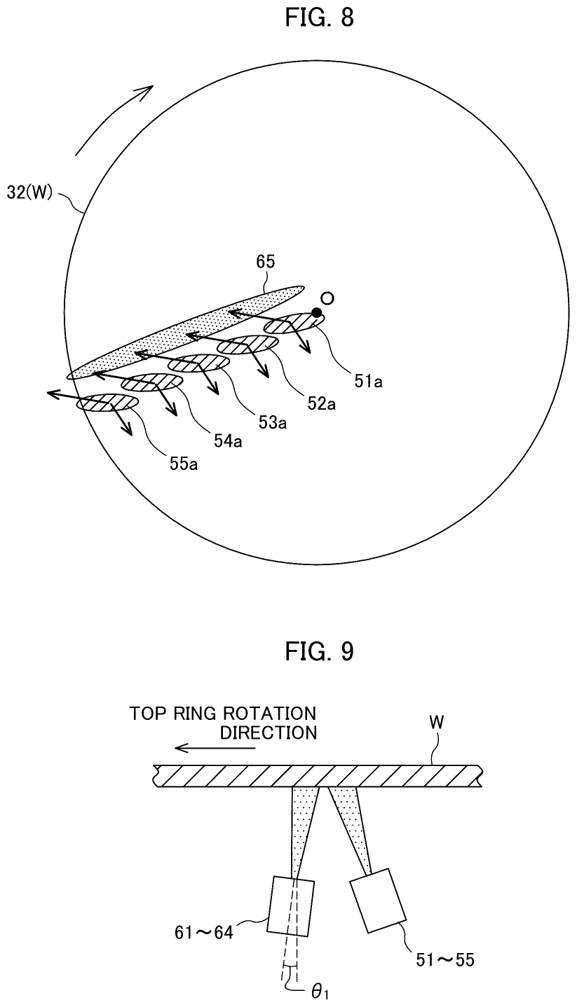

In the example in FIG. 7, the first substrate cleaning nozzle 51 is provided in a position corresponding to the vicinity of the center (the point O in FIG. 8) of the top ring 32, whereas the fifth substrate cleaning nozzle 55 is provided in a position corresponding to the vicinity of an outer circumferential part of the top ring 32. As shown in FIG. 7, the shapes of the cleaning liquid sprayed from the substrate cleaning nozzles 51 to 55 are substantially elongated oval shapes 51a to 55a, respectively. The major axes thereof are slightly tilted with respect to the radial direction of the top ring 32, while being positioned so as not to overlap with one another. While the top ring 32 is rotating, this configuration makes it easier for the cleaning liquid to be diffused over the entire surface of the substrate W.

The cleaning liquid squirted from the substrate cleaning nozzles 51 to 55 each being a two-fluid nozzle toward a substrate W collide with the surface of the substrate W and subsequently, except for a part of the cleaning liquid falling due to its own weight, the rest of the cleaning liquid forms a cleaning liquid flow moving toward the outer circumferential part of the top ring 32 (the substrate W) along the rotation direction of the top ring 32 and another cleaning liquid flow moving in the direction against the rotation direction of the top ring 32 (see the arrow in FIG. 8). Of those flows, the flow moving along the rotation direction of the top ring 32 is a fast flow due to the centrifugal force caused by the rotation of the top ring 32, so that the cleaning liquid containing the particles is easily discharged to the outside from the outer rim of the substrate W. As described herein, from a viewpoint of eliminating the particles, it is desirable to promote the flow of the cleaning liquid moving in the direction along the rotation direction of the top ring 32.

In contrast, the flow of the cleaning liquid moving in the direction against the rotation direction of the top ring 32 is a relatively slow flow, and later becomes a flow moving toward the outer circumference of the substrate W due to the centrifugal force associated with the rotation of the top ring 32. For this reason, the flow of the cleaning liquid moving in the direction against the rotation direction of the top ring 32 stays on the substrate W for a long period of time, which makes it easier for the particles in the cleaning liquid to re-adhere to the substrate W. For this reason, from a viewpoint of preventing the re-adhesion of the particles, it is desirable to inhibit the flow of the cleaning liquid moving in the direction against the rotation direction of the top ring 32.

Accordingly, in a substrate cleaning device according to the present embodiment, cleaning liquid spray angles of the substrate cleaning nozzles 51 to 55 are tilted toward the rotation direction of the top ring, as shown in FIG. 9. In comparison to perpendicularly spraying onto the top ring from underneath, this configuration increases the volume of the cleaning liquid in the flow moving along the rotation direction of the top ring and decreases the volume of the cleaning liquid in the flow moving against the rotation of the top ring. It is therefore possible to promote the particle elimination and to inhibit the re-adhesion of the particles to the substrate W.

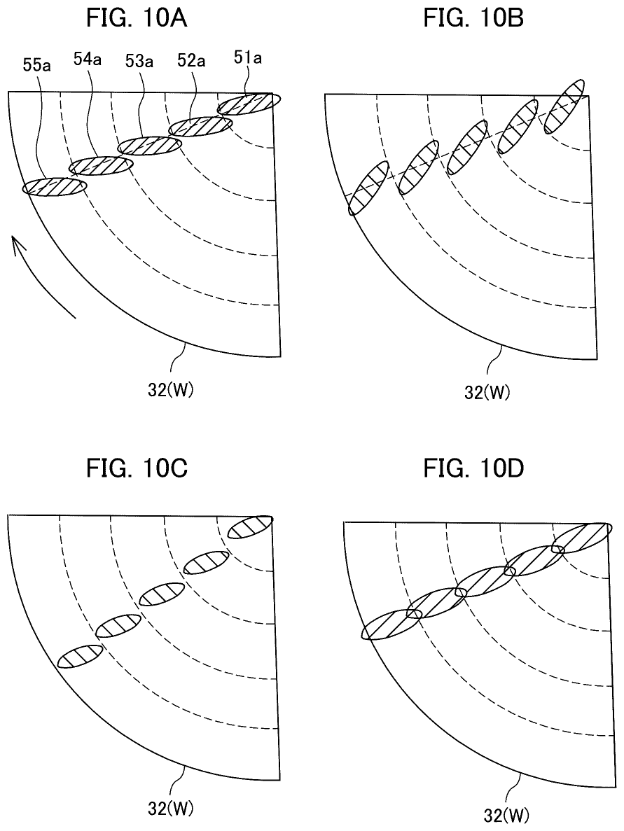

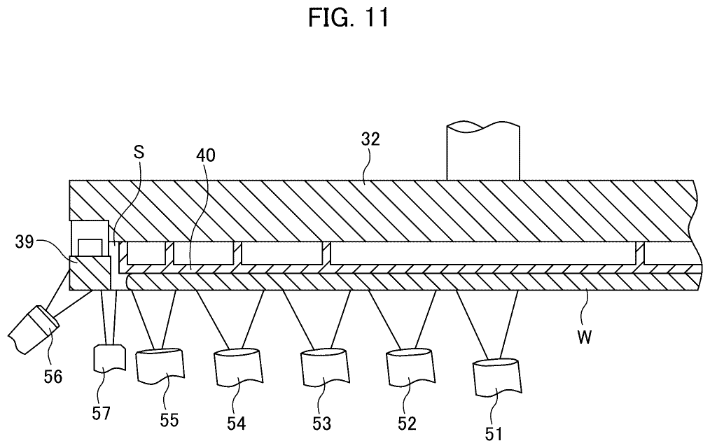

In this situation, as shown in FIG. 10A, as for the substrate cleaning nozzles 51 to 55 each being a two-fluid nozzle, the longitudinal directions of the cleaning liquid 51a to 55a sprayed therefrom are tilted, on the substrate surface, along the rotation direction (the direction of the arrow in FIG. 10A) of the top ring 32 (the substrate W), with respect to the radial direction of the top ring 32 (the substrate W) present in the cleaning position. In this situation, the cleaning liquid sprayed from each of the substrate cleaning nozzles flows, on the downstream side thereof, toward the outer circumferential side in the substrate radial direction. The cleaning liquid sprayed from each of the substrate cleaning nozzles forms, on the downstream side (the outer circumferential side in the radial direction), a fast liquid flow moving along the rotation of the top ring 32. It is therefore possible to efficiently discharge the cleaning liquid containing the particles to the outer circumference. Further, the cleaning liquid sprayed from each of the substrate cleaning nozzles flows, on the upstream side, toward the center of the substrate radial direction. The cleaning liquid sprayed from each of the substrate cleaning nozzles forms, on the upstream side (the central side in the radial direction), a slow liquid flow moving against the rotation of the top ring 32. Thus, the flow of the cleaning liquid containing the particles does not spread beyond a small area on the upstream side of each of the substrate cleaning nozzles, and the volume of the liquid staying in a central part of the substrate is kept small. It is therefore possible to inhibit the re-adhesion of the particles.

In contrast, as shown in FIG. 10B, when the longitudinal direction of the cleaning liquid (the hatching parts in the drawing) sprayed from each of the substrate cleaning nozzles was tilted, on the substrate surface, in the direction opposite to the rotation direction with respect to the radial direction of the top ring 32 (the substrate W), because the flow of the liquid moving toward the outer circumferential side in the substrate radial direction is generated on the upstream side of the cleaning liquid sprayed from the substrate cleaning nozzle, the flow of the liquid moving toward the outer circumferential side in the substrate radiation direction would be slow, which would degrade the capability to discharge the cleaning liquid containing the particles. Further, on the downstream side of the cleaning liquid sprayed from each of the substrate cleaning nozzles having a fast liquid flow, the cleaning liquid sprayed from the substrate cleaning nozzle would flow toward the central side in the substrate radial direction, which would make it easier for the cleaning liquid containing the particles to stay in the central part of the substrate and would make it easier for the particles to re-adhere. Consequently, it is desirable to determine the longitudinal directions of the cleaning liquid 51a to 55a sprayed from the substrate cleaning nozzles 51 to 55 as shown in FIG. 10A.

Further, as shown in FIG. 10A, it is desirable to ensure that the spray positions of the cleaning liquid implemented by the substrate cleaning nozzles 51 to 55 do not overlap with one another, while overlapping with one another with respect to the radial direction of the substrate W. With this arrangement, as the top ring 32 rotates, the cleaning liquid from the substrate cleaning nozzles 51 to 55 is directly sprayed onto the entire surface of the substrate W. In contrast, as shown in FIG. 10C, when there are regions that are not covered with respect to the radial direction of the substrate W (regions in the gaps between the spray areas of adjacently-positioned substrate cleaning nozzles), there would be regions where the effect of spraying using the two-fluid nozzles is not achieved. Further, as shown in FIG. 10D, when there were overlapping parts between the spray areas of the cleaning liquid, there would be a possibility that the cleaning liquid flows might collide with one another in the overlapping part, which might lower the speed of the cleaning liquid (the droplets) sprayed from the nozzles onto the substrate W and might lower cleaning effects.

FIG. 11 is a side view of the auxiliary cleaning unit 50. To simplify the drawing, the assisting nozzles 61 to 64 are omitted. The substrate cleaning nozzles 51 to 55 are provided while being tilted in the outer circumferential direction of the top ring 32 present in the cleaning position TP3. As the top ring 32 rotates, this configuration makes it easier for the cleaning liquid sprayed from the substrate cleaning nozzles 51 to 55 to be diffused toward the outer circumferential part of the top ring 32 and makes it easier to discharge the particles adhering to the substrate W and to the top ring 32, to the outside.

The retainer ring (RR) lateral face cleaning nozzle 56 is provided underneath the top ring 32 positioned in the cleaning position TP3 and, while the top ring 32 is rotating in the cleaning position TP3, sprays cleaning liquid 56a diagonally upward, toward the lateral face and the bottom face of the retainer ring 39. With this arrangement, it is possible to eliminate particles adhering to the lateral face of the retainer ring 39 after the polishing process.

Further, the RR-membrane gap cleaning nozzle 57 is provided underneath the top ring 32 positioned in the cleaning position TP3 and, while the top ring 32 is rotating in the cleaning position TP3, sprays cleaning liquid 57a vertically upward, toward a boundary part between the retainer ring 39 and the membrane 40. With this arrangement, it is possible to eliminate particles adhering to a gap S (see FIG. 11) between the retainer ring 39 and the membrane 40 after the polishing process.

As a result of the spraying of the cleaning liquid from the retainer ring (RR) lateral face cleaning nozzle 56 and the RR-membrane gap cleaning nozzle 57, there is a possibility that the particles adhering to the retainer ring 39 or the membrane 40 may be spattered toward the substrate W held by the top ring 32. To cope with this situation, the timing to stop the spraying of the cleaning liquid from the retainer ring (RR) lateral face cleaning nozzle 56 and the RR-membrane gap cleaning nozzle 57 is controlled so as to be at the same time as or to be earlier than the timing to stop the spraying of the cleaning liquid from the substrate cleaning nozzles 51 to 55.

If the spraying from the retainer ring (RR) lateral face cleaning nozzle 56 and the RR-membrane gap cleaning nozzle 57 was stopped later than the spraying from the substrate cleaning nozzles 51 to 55, there would be a possibility that the particles might be spattered onto the substrate W. By ensuring that the timing to stop the spraying from the retainer ring (RR) lateral face cleaning nozzle 56 and the RR-membrane gap cleaning nozzle 57 is at the same time as or is earlier than the timing to stop the spraying of the cleaning liquid from the substrate cleaning nozzles 51 to 55, it is possible, even if the particles are spattered onto the substrate W, to eliminate the particles with the spraying of the cleaning liquid from the substrate cleaning nozzles 51 to 55.

As the cleaning liquid sprayed from the retainer ring (RR) lateral face cleaning nozzle 56 and the RR-membrane gap cleaning nozzle 57, it is possible to use, for example, pure water, an acidic or alkaline chemical solution or surfactant, a substance to which an ultrasound wave is applied, high-speed droplets or mist generated by pressure-spraying a fluid mixture (two fluids) of gas and liquid (e.g., pure water) containing a small amount of carbon dioxide for inhibiting static electricity, or liquid to be high-speed jet sprayed.

In FIGS. 6 and 7, the assisting nozzles 61 to 64 structure a spray unit for assisting the substrate cleaning and are each a one-fluid nozzle that blows the cleaning liquid onto the surfaces of the substrate, while being linearly arranged underneath the top ring 32, while the top ring 32 is in the cleaning position TP3.

The assisting nozzles 61 to 64 may be selected from among: spray nozzles (e.g., one-fluid nozzles spreading in a fan shape), nozzles that pressure-spray a fluid mixture (two fluids) of liquid (e.g., pure water) and gas, nozzles that generate a high-speed jet spray, and nozzles that apply ultrasound waves. As for the type of the liquid supplied to the assisting nozzles 61 to 64, it is possible to use, for example, pure water, an acidic or alkaline chemical solution or surfactant, liquid containing a small amount of carbon dioxide for inhibiting static electricity, water saturated with N₂ gas, or water containing fine bubbles.

The assisting nozzles 61 to 64 upwardly spray cleaning liquid (e.g., pure water) 61a to 64a each having a substantially oval shape (see FIG. 7) onto the surface of the substrate W that is rotating in the cleaning position TP3 together with the top ring 32, in the direction of the arrow shown in FIG. 7. The assisting nozzles 61 to 64 are arranged so that the cleaning liquid 61a to 64a being sprayed overlap with each other. The cleaning liquid 61a to 64a squirted from all the assisting nozzles 61 to 64 integrally form cleaning liquid 65 (see FIG. 8) having a single linear shape.

The cleaning liquid sprayed from the assisting nozzles 61 to 64 onto the substrate W moves, as the top ring 32 rotates, toward the outer circumference of the substrate W due to centrifugal force. In the present embodiment, the spray position of the cleaning liquid from the assisting nozzles 61 to 64 onto the substrate W is on the downstream side of the spray positions of the cleaning liquid from the substrate cleaning nozzles 51 to 55, with respect to the rotation direction of the top ring 32 (see FIG. 8). This arrangement makes it easier for the cleaning liquid sprayed from the substrate cleaning nozzles 51 to 55 onto the substrate W to move toward the outer circumferential part of the substrate W, together with the cleaning liquid from the assisting nozzles 61 to 64, and thus enhances the capability to discharge the particles.

Further, the cleaning liquid squirted from the assisting nozzles 61 to 64 has the linear shape including the vicinity of the center of the top ring 32. With this arrangement, as the top ring 32 rotates, it is possible to make the liquid adhere over a large area including a central part of the substrate W supported by the top ring 32. It is therefore possible to effectively prevent the substrate W from being dry.

As shown in FIG. 9, the assisting nozzles 61 to 64 are tilted toward the substrate cleaning nozzles 51 to 55. This arrangement makes it easier for the cleaning liquid from the assisting nozzles 61 to 64 to interfere with the cleaning liquid sprayed from the substrate cleaning nozzles 51 to 55 onto the substrate W. It is therefore possible to efficiently move the cleaning liquid sprayed from the substrate cleaning nozzles 51 to 55 and adhering to the substrate W, to the outside. It is desirable to arrange a spray angle θ1 (relative to the vertical direction) of each of the assisting nozzles 61 to 64 to be in the range of 0° to 15°.

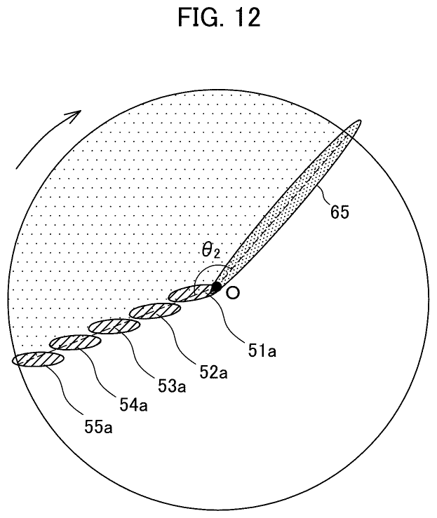

In the present embodiment, because the assisting nozzles 61 to 64 are provided in positions close to the substrate cleaning nozzles 51 to 55, the assisting nozzles exert high effects in promoting the discharging of the cleaning liquid and inhibiting the re-adhesion of the particles. In contrast, as the positions of the assisting nozzles 61 to 64 become farther away from the substrate cleaning nozzles 51 to 55, although the effect of controlling the liquid flows exerted by the assisting nozzles becomes lower, the certainty with which the assisting nozzles are able to cause the liquid to flow toward the outer circumference becomes higher, because the liquid flows more slowly and the liquid volume becomes smaller. Thus, even if there is certain distance, the effect of eliminating the cleaning liquid exerted by the assisting nozzles is still achieved. In contrast, if the spray position of the assisting nozzles 61 to 64 overlapped with the spray positions of the substrate cleaning nozzles 51 to 55, there would be a possibility that the cleaning effect of the substrate cleaning nozzles 51 to 55 might be hindered. For this reason, as shown in FIG. 12, the assisting nozzles are arranged in such a manner that the spray position of the cleaning liquid 65 from the assisting nozzles fits in the range of an angle θ2 from a reference line connecting the substrate center to the center of the spray position of the cleaning liquid 55a from the substrate cleaning nozzle 55. It is desirable to determine the angle θ2 to be in the range of 0° to 180° and, more preferably, in the range of 0° to 90° in particular.

It is desirable to ensure that the timing to stop the spraying of the cleaning liquid from the assisting nozzles 61 to 64 is later than the timing to stop the spraying of the cleaning liquid from the substrate cleaning nozzles 51 to 55, the retainer ring (RR) lateral face cleaning nozzle 56, and the RR-membrane gap cleaning nozzle 57. With this arrangement, it is possible to wash away the cleaning liquid adhering to the substrate W from the substrate cleaning nozzles 51 to 55, the retainer ring (RR) lateral face cleaning nozzle 56, and the RR-membrane gap cleaning nozzle 57.

Provided inside the housing 11 is the controlling unit 15 that controls operations of functional units of the substrate polishing device 10. The controlling unit 15 may be a generic computer, for example, and includes a CPU, a storage unit (a memory) 70 storing a control program therein, a display unit, and the like. Further, the controlling unit 15 includes an input unit that receives external inputs. In this situation, the external inputs may include mechanical operations performed by a user and signals that are input by external devices in a wired or wireless manner.

By running a control program stored in the storage unit (memory) 70, the controlling unit 15 controls movements of machines in the substrate polishing device 10. The control program for controlling operations of the substrate polishing device 10 may be installed in advance in the computer structuring the controlling unit 15, may be stored in a storage medium such as a DVD, BD, or an SSD, or may be installed in the controlling unit 15 via the Internet.

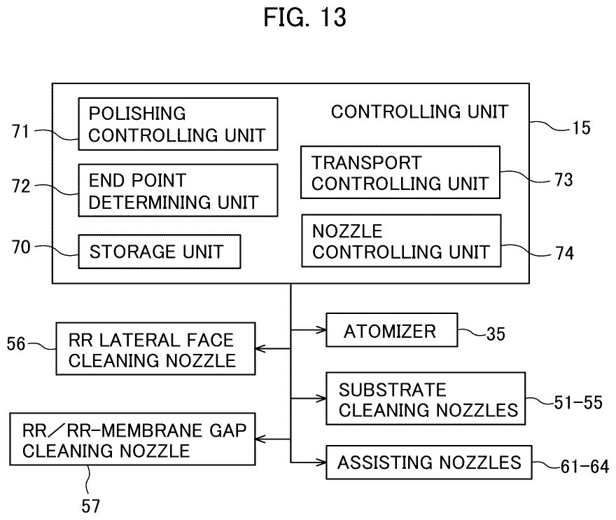

FIG. 13 shows an example of a functional block diagram of the controlling unit 15 of the substrate polishing device 10. The controlling unit 15 includes the storage unit 70, a polishing controlling unit 71, an end point determining unit 72, a transport controlling unit 73, and a nozzle controlling unit 74. The polishing controlling unit 71 controls the rotations of the polishing table 30 and the top ring 32 and controls the pressure in the pressure chambers P1 to P5. By using an optical sensor (not shown) or the like, the end point determining unit 72 determines whether or not a polishing amount of each substrate W has reached a setting value and, if the value is reached, ends the substrate polishing process. The transport controlling unit 73 controls the transport of the substrate W within the substrate polishing device 10, including the transport of the substrate W in the polishing units 13A to 13D.

The nozzle controlling unit 74 is connected to the atomizer 35, the substrate cleaning nozzles 51 to 55, the RR lateral face cleaning nozzle 56, the RR-membrane gap cleaning nozzle 57, and the assisting nozzles 61 to 64 and controls the spraying of the cleaning liquid from the nozzles.

In this situation, when the cleaning liquid or the like is sprayed from the various types of nozzles structuring the auxiliary cleaning unit 50 while the top ring 32 is being rotated in the cleaning position, droplets containing the particles that adhered to the substrate W, the top ring 32, and the retainer ring 39 are spattered from the outer circumference of the top ring 32. If the droplets spattered from the top ring 32 reached the polishing table 30, there would be a possibility that the polishing pad 31 might be contaminated and might cause scratches at the time of polishing a next substrate W.

For this reason, the positions of the various types of nozzles and the rotation direction of the top ring are set so that the cleaning liquid or the like from the various types of nozzles structuring the auxiliary cleaning unit 50 flows in the direction toward the handover position TP2. In the example of FIG. 7, when the auxiliary cleaning unit 50 is positioned on the left side relative to the center of the top ring 32, control is exercised so as to rotate the top ring 32 in the clockwise direction. On the contrary, when the auxiliary cleaning unit 50 is positioned on the right side relative to the center of the top ring 32, control is exercised so as to rotate the top ring 32 in the counterclockwise direction. With these arrangements, as the top ring 32 rotates, the cleaning liquid and rinse liquid from the various types of nozzles structuring the auxiliary cleaning unit 50 flow in the direction toward the handover position. It is therefore possible to prevent the droplets spattered from the top ring 32 from reaching the polishing table 30.

Further, after the polishing process is performed on the substrate W, a dressing process and a cleaning process are performed on the polishing pad 31 by the dresser 34 that is caused, by a raising/lowering/swinging mechanism (not shown), to swing in a substantially radial direction thereof while being in contact with the polishing pad 31, while the cleaning liquid is sprayed from the atomizer 35 onto the polishing pad 31 which keeps rotating integrally with the polishing table 30. The controlling unit 15 exercises control so that the timing to end the spraying of the cleaning liquid from the atomizer 35 (the timing to end the cleaning of the polishing pad 31) is at the same time as or later than the timing to end the spraying of the cleaning liquid or the like from the various types of nozzles structuring the auxiliary cleaning unit 50.

If the timing to end the spraying of the cleaning liquid or the like from the nozzles in the auxiliary cleaning unit 50 were later than the timing to end the spraying of the cleaning liquid from the atomizer 35, there would be a possibility that droplets might be spattered from the top ring 32 onto the polishing table 30. However, by ensuring that the spraying from the atomizer 35 and the spraying from the auxiliary cleaning unit 50 are stopped at the same time, it is possible to lower the possibility that the particles may be spattered onto the polishing table 30. Furthermore, by ensuring that the timing to end the spraying of the cleaning liquid from the atomizer 35 is later than the timing to end the spraying of the cleaning liquid or the like from the nozzles in the auxiliary cleaning unit 50, it is possible, even if droplets are spattered from the top ring 32 onto the polishing table 30 due to the cleaning process performed by the auxiliary cleaning unit 50, to eliminate the droplets with the spraying of the cleaning liquid from the atomizer 35.

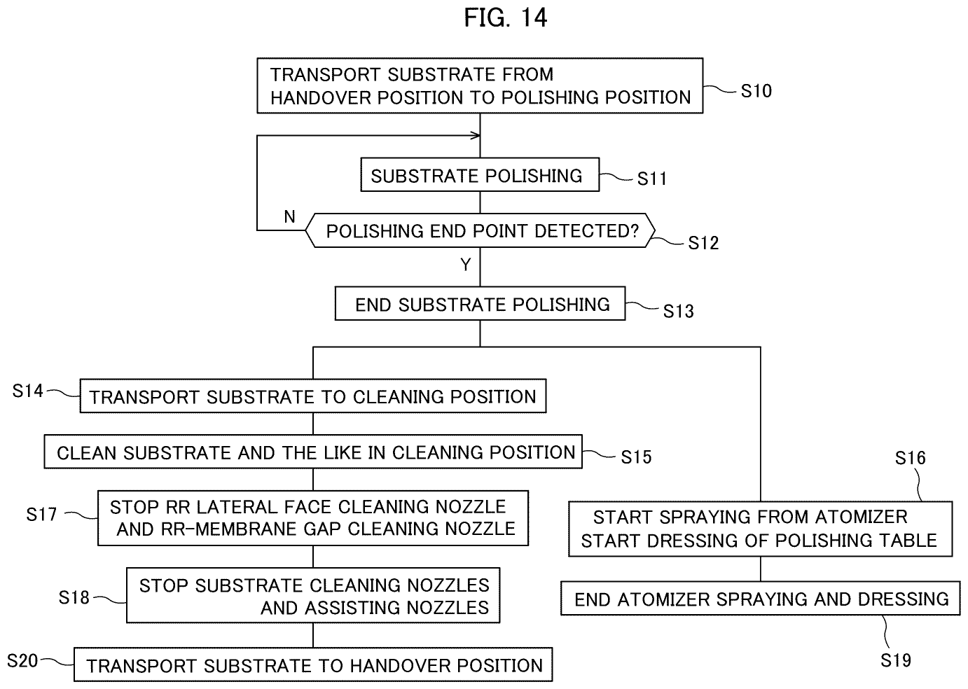

The substrate polishing process and the post-polishing cleaning process performed by the substrate polishing device 10 configured as described above will be described below, with reference to the flowchart in FIG. 14. When a substrate W has been transported to the polishing unit 13A, the top ring 32 holds the substrate W with vacuum adsorption in such a position that the substrate W is surrounded by the retainer ring 39 and transports the substrate W from the handover position TP2 to the polishing position TP1 (step S10). By pressing the substrate W that has reached the polishing position TP1 against the polishing pad 31, the polishing unit 13A performs the polishing process on the substrate W (step S11). By measuring the thickness of coating on the substrate W during the substrate polishing process, it is determined whether or not the prescribed coating thickness has been reached (whether a polishing end point has been reached) (step S12). When the polishing end point has been reached, the substrate polishing process is ended (step S13).

After that, the top ring 32 is moved to the cleaning position TP3 (step S14). When the top ring 32 has reached the cleaning position TP3, the various types of nozzles structuring the auxiliary cleaning unit 50 are driven while the top ring 32 is being rotated, so that the cleaning process is performed on the substrate W, the top ring 32, and the retainer ring 39 (step S15). As a result, particles adhering to the substrate W, the top ring 32, and the retainer ring 39 due to the substrate polishing process are discharged to the outside of the top ring 32.

In this situation, as for the substrate cleaning nozzles 51 to 55 each being a two-fluid nozzle, the longitudinal direction of the cleaning liquid 51a to 55a sprayed therefrom are tilted along the rotation direction of the substrate W. At that time, a large part of the cleaning liquid 51a to 55a sprayed from the substrate cleaning nozzles flows toward the downstream side (in the direction toward the outer circumference in the radial direction), whereas a part of the cleaning liquid 51a to 55a flows toward the upstream side (in the direction toward the center in the radial direction). Because the cleaning liquid 51a to 55a moving toward the downstream side (in the direction toward the outer circumference in the radial direction) forms a fast liquid flow, it is possible to efficiently discharge the cleaning liquid containing the particles to the outer circumference. In contrast, because the cleaning liquid 51a to 55a sprayed from the substrate cleaning nozzles and moving toward the upstream side (in the direction toward the center in the radial direction) forms a liquid flow slower than the liquid flow toward the downstream side, there is a possibility that the cleaning liquid containing the particles may stay in a central part of the substrate, and the particles may adhere.

Because the substrate cleaning nozzles 51 to 55 are tilted toward the downstream side in the rotation direction of the substrate W, the volume in the flow of the cleaning liquid 51a to 55a moving along the rotation direction of the top ring is increased, whereas the volume in the flow of the cleaning liquid moving against the rotation direction is decreased. It is therefore possible to prevent the particles from staying on the substrate W and re-adhering to the substrate W.

In addition, with respect to the rotation direction of the substrate W, the assisting nozzles 61 to 64 are provided on the downstream side of the substrate cleaning nozzles 51 to 55, while being tilted toward the substrate cleaning nozzles 51 to 55. The cleaning liquid sprayed from the assisting nozzles 61 to 64 makes it easier for the cleaning liquid from the substrate cleaning nozzles 51 to 55 to flow toward the outer circumferential part of the substrate W. Consequently, it is possible to efficiently discharge the cleaning liquid containing the particles to the outside of the substrate W.

At the same time as step S14 described above starts, the cleaning liquid is, at step S16, sprayed onto the polishing pad 31 by driving the atomizer 35, and also, the dressing process on the polishing pad 31 is started by driving the dresser 34. In this manner, the cleaning process on the substrate W held by the top ring 32 and the dressing process on the polishing pad 31 are performed in parallel to each other. The dressing process and the cleaning process on the polishing pad 31 are performed in parallel to the post-polishing cleaning process executed by the auxiliary cleaning unit 50 on the top ring 32 and the substrate W.

After a predetermined period has elapsed, the RR lateral face cleaning nozzle 56 and the RR-membrane gap cleaning nozzle 57 are stopped, and the cleaning process on the retainer ring 39 and the membrane 40 is thus ended (step S17). After that, the substrate cleaning nozzles 51 to 55 and the assisting nozzles 61 to 64 are stopped (step S18). Thus, the post-polishing cleaning process on the substrate W has finished.

After that, the spraying of the cleaning liquid by the atomizer 35 and the dressing process on the polishing pad 31 are ended (step S19). With this arrangement, it is possible to eliminate the possibility that the droplets from the top ring 32 containing particles remain on the polishing pad 31 due to the post-polishing cleaning process. After that, the top ring 32 is moved to the handover position TP2 (step S20), and a post-polishing substrate W is transported toward the cleaning section 14.

### Second Embodiment

A second embodiment is different from the first embodiment described above in that the assisting nozzles are provided on the upstream side in the rotation direction of the substrate W, relative to the substrate cleaning nozzles. In the following descriptions, some of the constituent elements that are the same as those in the above substrate polishing device according to the first embodiment will be referred to by using the same reference numerals, and detailed descriptions thereof will be omitted.

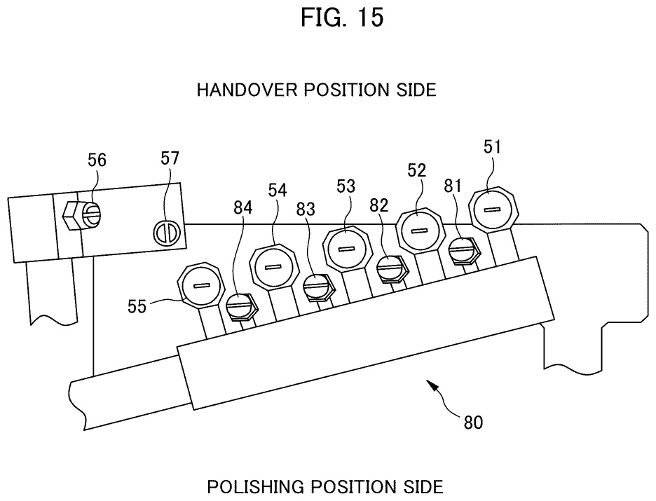

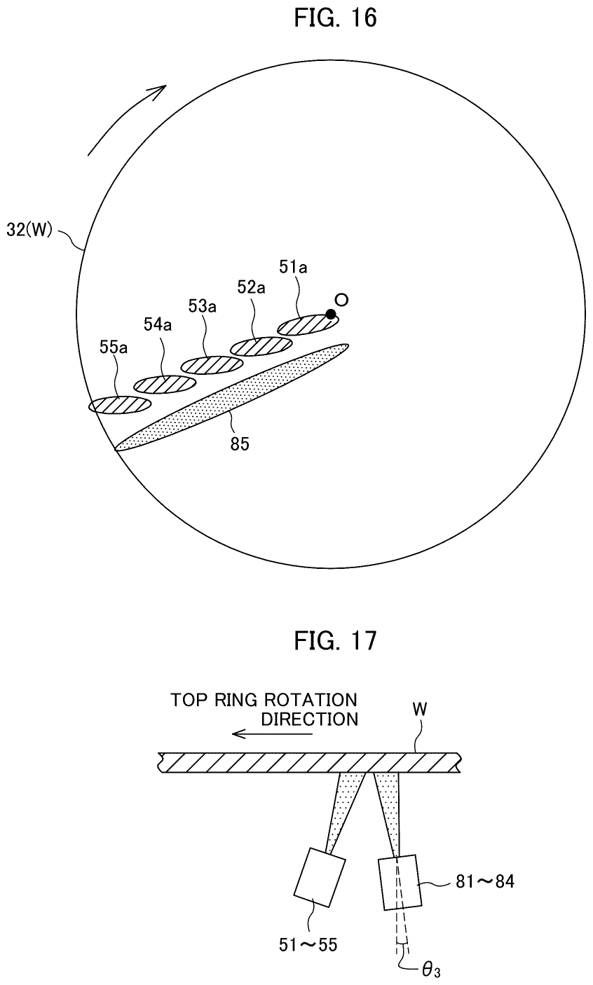

In FIGS. 15 to 17, the substrate cleaning nozzles 51 to 55 are tilted in a direction against the rotation direction of the top ring, so that the cleaning liquid 51a to 55a from the substrate cleaning nozzles 51 to 55 is sprayed onto the substrate W in the direction against the rotation direction of the top ring. In that situation, the volume in the flow moving along the rotation direction of the top ring is smaller and the volume in the flow moving against the rotation direction of the top ring is larger than in the situation where the top ring is perpendicularly sprayed from underneath.

In this situation, assisting nozzles 81 to 84 are provided on the upstream side in the rotation direction of the substrate W, relative to the substrate cleaning nozzles 51 to 55. While cleaning liquid 85 squirted from the assisting nozzles 81 to 84 serves as a wall, it is possible to direct the flows of the cleaning liquid 51a to 55a sprayed from the substrate cleaning nozzles 51 to 55 toward the outside of the substrate W. As a result, because the cleaning liquid 51a to 55a is caused to flow toward the outside, it is possible to prevent the particles from re-adhering to the substrate W.

In addition, as shown in FIG. 17, the assisting nozzles 81 to 84 are tilted toward the substrate cleaning nozzles 51 to 55, so as to make it easier for the cleaning liquid 85 from the assisting nozzles 81 to 84 to interfere with the cleaning liquid sprayed from the substrate cleaning nozzles 51 to 55 onto the substrate W. As a result, it is possible to efficiently move the cleaning liquid spayed from the substrate cleaning nozzles 51 to 55 and adhering to the substrate W, toward the outside. In this situation, it is desirable to arrange a spray angle θ3 (relative to the vertical direction) of each of the assisting nozzles 81 to 84 to be in the range of 0° to 15°.

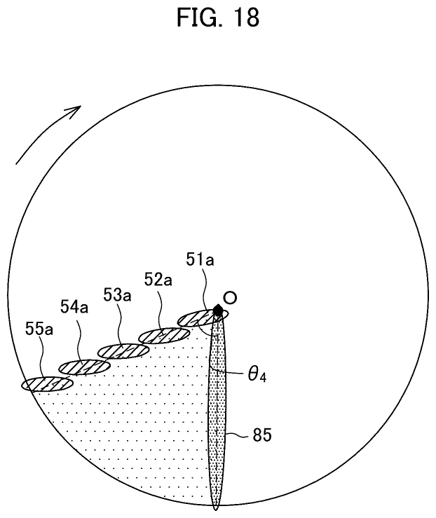

In the second embodiment, because the assisting nozzles 81 to 84 are provided in positions close to the substrate cleaning nozzles 51 to 55, the assisting nozzles exert a high effect in discharging the cleaning liquid. As the positions of the assisting nozzles 81 to 84 become farther away from the substrate cleaning nozzles 51 to 55, although the effect of discharging the cleaning liquid exerted by the assisting nozzles becomes lower, the effect of eliminating the cleaning liquid exerted by the assisting nozzles is still achieved, even if there is a distance of a certain extent, because the substrate held by the top ring is rotating. In contrast, if the spray position of the assisting nozzles 81 to 84 overlapped with the spray positions of the substrate cleaning nozzles 51 to 55, there would be a possibility that the spraying effect of the two-fluid jets by the substrate cleaning nozzles 51 to 55 might be hindered and that the cleaning effect might be degraded. In addition, when the spray position of the assisting nozzles 81 to 84 were close to the spray positions of the substrate cleaning nozzles 51 to 55, it is feared that the thickness of a liquid film in the spray positions of the substrate cleaning nozzles might become too large, which might lower physical force applied to the substrate surface by the substrate cleaning nozzles and might hinder the removal of the particles by the substrate cleaning nozzles. For this reason, as shown in FIG. 18, the assisting nozzles are arranged in such a manner that the spray position of the cleaning liquid 65 from the assisting nozzles fits in the range of an angle θ4 from a reference line connecting the substrate center to the center of the spray position of the cleaning liquid 55a from the substrate cleaning nozzle 55. It is desirable to determine the angle θ4 to be in the range of 0° to 180° and, more preferably, in the range of 0° to 60° in particular.

### Third Embodiment

A third embodiment is different from the first embodiment described above in that assisting nozzles are provided on both the upstream side and the downstream side in the rotation direction of the substrate W, relative to the substrate cleaning nozzles. In the following descriptions, some of the constituent elements that are the same as those in the above substrate polishing device according to the first embodiment will be referred to by using the same reference numerals, and detailed descriptions thereof will be omitted.

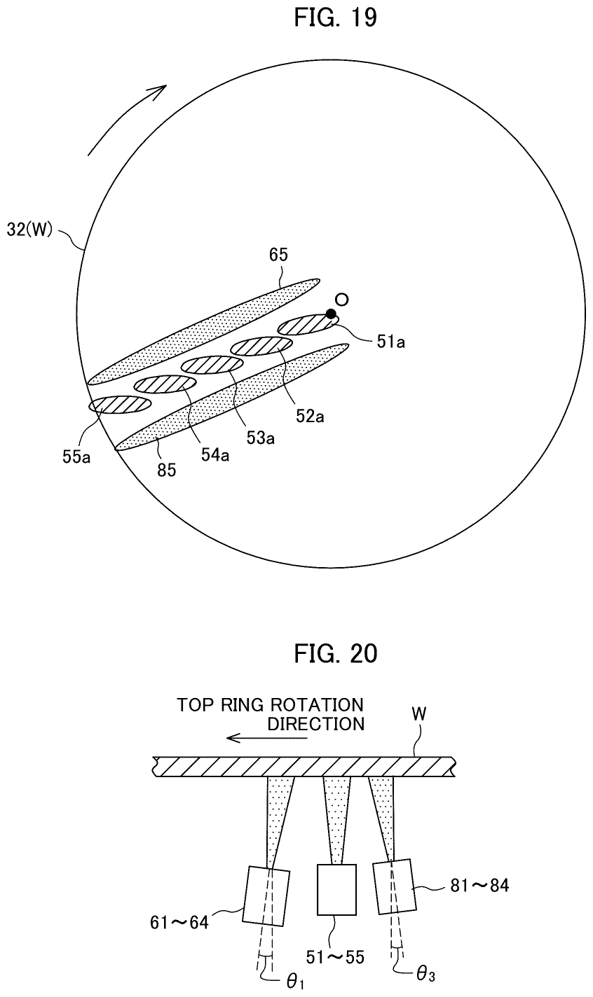

In FIGS. 19 and 20, the spray angles of the cleaning liquid from the substrate cleaning nozzles 51 to 55 onto the substrate W are arranged to be the vertical direction (the direction perpendicular to the surface of the substrate W). In this situation, the volume in the flow moving along the rotation direction of the top ring is smaller than that in the situation where the spraying of the cleaning liquid is tilted along the rotation direction of the top ring 32, but is larger than that in the situation where the spraying of the cleaning liquid is against the rotation direction of the top ring 32. Further, the volume in the flow of the cleaning liquid moving in the direction against the rotation direction of the top ring 32 is larger than that in the situation where the spraying of the cleaning liquid is tilted along the rotation direction of the top ring 32, but is smaller than that in the situation where the spraying of the cleaning liquid is against the rotation direction of the top ring.

In that situation, by arranging first assisting nozzles 61 to 64 on the downstream side in the rotation direction of the substrate W, relative to the substrate cleaning nozzles 51 to 55, it is possible, as described in the first embodiment, to efficiently discharge the cleaning liquid flowing along the rotation direction of the substrate W, to the outside. In addition, by arranging second assisting nozzles 81 to 84 on the upstream side in the rotation direction of the substrate W, relative to the substrate cleaning nozzles 51 to 55, it is possible to direct the flow squirted from the substrate cleaning nozzles 51 to 55 and moving toward the center of the substrate W, to the outside of the substrate W. It is therefore possible to prevent the particles from re-adhering to the substrate W.

Furthermore, as shown in FIG. 20, the first assisting nozzles 61 to 64 (on the downstream side) and the second assisting nozzles 81 to 84 (on the upstream side) are tilted toward the substrate cleaning nozzles 51 to 55. This arrangement makes it easier for the cleaning liquid from the assisting nozzles 61 to 64 and 81 to 84 to interfere with the cleaning liquid sprayed from the substrate cleaning nozzles 51 to 55 onto the substrate W. It is therefore possible to efficiently move the cleaning liquid from the substrate cleaning nozzles 51 to 55 adhering to the substrate W, to the outside. It is desirable to arrange both the tilt angle θ1 (relative to the vertical direction) of each of the first assisting nozzles 61 to 64 and the tilt angle θ3 (relative to the vertical direction) of each of the second assisting nozzles 81 to 84 to be in the range of 0° to 15°. The tilt angles θ1 and 03 of the two may be equal to each other or may be different from each other.

### (Modification Examples)

In the above embodiments, the examples were described in which the five substrate cleaning nozzles and the four assisting nozzles were provided; however, it is possible to change the quantities of the assisting nozzles and the substrate cleaning nozzles as appropriate. However, it is desirable to ensure that the cleaning liquid squirted from the substrate cleaning nozzles spreads over the entire radial direction of the substrate W. In addition, for the purpose of discharging the cleaning liquid staying near the center of the substrate W to the outer circumferential part, it is desirable to arrange the assisting nozzles in the vicinity of a central part (within the area of 50 mm from the center) of the substrate W.

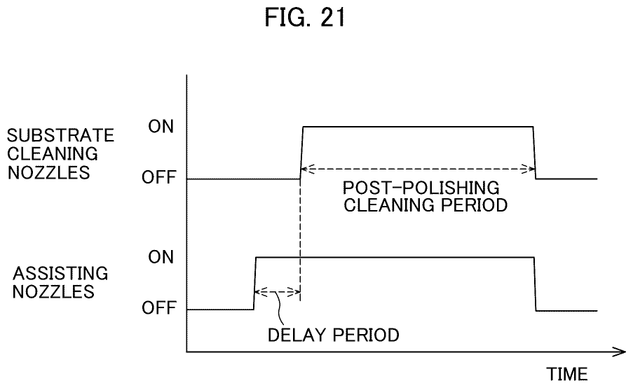

It is also acceptable to install a valve with each of the substrate cleaning nozzles and the assisting nozzles, so as to independently control driving timing of the assisting nozzles and the substrate cleaning nozzles. In FIG. 21, for the substrate W that has reached the cleaning position, the assisting nozzles are driven first, and the substrate cleaning nozzles are driven after a delay period (e.g., a predetermined period equal to or shorter than 1 second) has elapsed. With this arrangement, it is possible to prevent the substrate W from getting dry before the post-polishing cleaning process performed by the substrate cleaning nozzles. In another example, it is also acceptable to install a flow meter with each of the substrate cleaning nozzles and the assisting nozzles, so as to independently control the amounts of cleaning liquid squirted from the valves.

In the above embodiments, the installation angles of the assisting nozzles are fixed in the directions parallel to and perpendicular to the surface of the substrate W. However, it is also acceptable to make one or both of the installation angles adjustable.

During process standby periods in which the substrate W is not in the cleaning position (while the post-polishing cleaning process is not performed on the substrate W), it is desirable to intermittently squirt a small amount of super pure water from the nozzles structuring the auxiliary cleaning unit 50. With this arrangement, it is possible to inhibit occurrence of bacteria and the like.

The above embodiments are described for the purpose of enabling a person having ordinary knowledge in the technical field to which the present invention belongs, to carry out the present invention. A person skilled in the art would naturally be able to conceive of various modification examples of the above embodiments, and the technical concept of the present invention is applicable to other embodiments. The present invention is not limited by the described embodiments and is to be interpreted as having the broadest scope conforming to the technical concept defined in the claims.

What is claimed is:

1. A substrate cleaning device that cleans a surface of a substrate having been polished and is provided for a polishing device including a polishing table having a polishing surface for performing substrate polishing and a top ring for holding and pressing the substrate against the polishing surface by using a membrane while causing a retainer ring to surround an outer circumferential part of the substrate, wherein
the top ring is movable between a polishing position where the substrate polishing is performed above the polishing table and a handover position where the substrate is handed over in a lateral position relative to the polishing table,
the substrate cleaning device is provided in correspondence with a cleaning position between the polishing position and the handover position,
the substrate cleaning device comprises:
a first spray unit that sprays cleaning liquid toward the substrate present in the cleaning position and a second spray unit that sprays cleaning liquid toward the substrate present in the cleaning position,
the second spray unit is provided on either a downstream side or an upstream side of the first spray unit, with respect to a rotation direction of the top ring present in the cleaning position, and
the cleaning liquid from the second spray unit urges the cleaning liquid sprayed from the first spray unit toward the outer circumferential part of the substrate.

2. The substrate cleaning device according to claim 1, wherein
a spray nozzle structuring the second spray unit is tilted toward the first spray unit.

3. The substrate cleaning device according to claim 1, wherein
the second spray unit is provided on the downstream side of the first spray unit, with respect to the rotation direction of the top ring present in the cleaning position.

4. The substrate cleaning device according to claim 1, wherein
the second spray unit is provided on the upstream side of the first spray unit, with respect to the rotation direction of the top ring present in the cleaning position.

5. The substrate cleaning device according to claim 1, wherein
the second spray unit is provided on the upstream side and the downstream side of the first spray unit, with respect to the rotation direction of the top ring present in the cleaning position.

6. The substrate cleaning device according to claim 1, wherein
the first spray unit sprays the cleaning liquid to have a substantially oval shape, while a longitudinal direction of the cleaning liquid is tilted along the rotation direction of the top ring with respect to a radial direction of the top ring present in the cleaning position.

7. The substrate cleaning device according to claim 1, wherein
the first spray unit and the second spray unit are capable of spraying the cleaning liquid independently of each other.

8. The substrate cleaning device according to claim 1, further comprising: a spray unit that sprays cleaning liquid toward a position between the membrane and the retainer ring and/or toward the retainer ring.

9. A substrate polishing device comprising:
the polishing table and the top ring;
the substrate cleaning device according to claim 1; and
a controlling unit that controls operations of the top ring and the substrate cleaning device.

10. The substrate polishing device according to claim 9, wherein
the controlling unit exercises control so that the first spray unit sprays the cleaning liquid after the second spray unit sprays the cleaning liquid.
